(19) United States
(12) Patent Application Publication
(10) Pub. No.: US 2002/0093086 A1
(43) Pub. Date: Jul. 18, 2002

(54) Semiconductor wafer backside grinding apparatus and method

(76) Inventor: Young Ki Lee, Suwon-city (KR)

Correspondence Address: The Law Offices of Eugene M Lee, PLLC, Suite 1200, 2111 Wilson Boulevard, Arlington, VA, 22201, US

(21) Appl. No.: 09/995,767

(22) Filed: Nov. 29, 2001

(30) Foreign Application Priority Data
Jan. 17, 2001 (KR) 2000-2673

(51) Int. Cl. H01L 23/52

(52) U.S. Cl. 257/690

(57) ABSTRACT

A semiconductor wafer backside grinding apparatus and method, wherein a wafer bending protector having a pre-determined strength is attached to a wafer to prevent the wafer from bending and also to protect the wafer against impurities that may penetrate the wafer during a grinding process. A wafer becomes thinner during a wafer backside grinding process and is prone to becoming bent. The wafer bending protector and the method employing the wafer bending protector prevents the wafer from becoming bent and allows for transfer of the ground wafer without wafer breakage.

### BACKGROUND OF THE INVENTION

1. Field of the Invention

The present invention relates to a semiconductor wafer backside grinding apparatus and a method thereof. More particularly, the present invention relates to a wafer bending protector and a wafer bending protecting method in which wafer bending may be inhibited in a semiconductor wafer backside grinding process.

2. Description of Related Art

After completing an electric circuit patterning process to one side of a wafer in a semiconductor manufacturing process, a backside grinding process to grind the other side of the wafer is generally performed.

In the wafer backside grinding process, unnecessary layers, such as a polysilicon layer or an oxide layer, which are attached to a wafer backside while the patterning process is performed, are removed. In the wafer backside grinding process, a backside of a wafer is polished to make the wafer thinner, resulting in reduced resistance of a device's electric conductivity and improved heat conductivity of the wafer.

The thickness of a wafer produced by the conventional wafer backside grinding process is around 300 μm to 600 μm depending on the kind of semiconductor device formed on the wafer, and the thickness of a wafer less than around 300 μm cannot be attained in the conventional wafer backside grinding process.

The thinner a wafer is after a backside grinding process, the more prone the wafer is to be bent. Moreover, the more the wafer is bent, the less likely the wafer is to be transferred and loaded into a wafer cassette properly. As a result, the thinner the wafer, the higher the wafer breakage ratio is. It is for these reasons that the conventional backside grinding process has difficulty attaining a thinner wafer.

In other words, wafer bending results in significant problems in a semiconductor wafer manufacturing process such as: improper loading into a wafer cassette, an adhesion failure in a transfer robot and an adhesion failure in an adhesion apparatus for transferring a wafer. The phenomena described above are more severe when the thickness of a wafer is less than 300 μm. Therefore, using conventional apparatus and methods, a semiconductor device with a wafer thickness of 100 μm or less is almost never produced, and more particularly, a wafer with a thickness of 100 μm or less and with a diameter of twelve inches or more, cannot be produced.

### SUMMARY OF THE INVENTION

To overcome the problems described above, it is a feature of an embodiment of the present invention to provide a semiconductor wafer backside grinding apparatus in which bending of a wafer as a result of the wafer becoming thinner during a wafer backside grinding process may be prevented.

Another feature of an embodiment of the present invention is to provide a semiconductor wafer backside grinding method in which bending of a wafer as a result of the wafer becoming thinner during a wafer backside grinding process may be prevented.

In an embodiment of the present invention, there is provided a semiconductor wafer backside grinding apparatus comprising a wafer bending protector having a pre-determined strength attachable to a wafer to prevent the wafer from becoming bent and to prevent impurities from penetrating the wafer in a grinding process. It is preferable for the wafer bending protector to comprise a transparent material so that one side of the wafer attached to the wafer bending protector may be visible. It is also preferable for an adhesive to coat one side of the wafer bending protector for attaching to the wafer.

In another embodiment of the present invention there is provided a wafer fabrication method in a semiconductor wafer backside grinding apparatus, the wafer fabrication method comprising a process in which a wafer bending protector is attached to a wafer and a process in which the wafer bending protector is separated from the wafer. The process of attaching a wafer bending protector with a pre-determined strength to a wafer prevents wafer bending and impurities from penetrating a patterned side of the wafer in a grinding process. In the process of separating the wafer bending protector, the wafer bending protector is preferably separated from one side of the wafer. The wafer bending protector preferably comprises a transparent material so that one side of the wafer attached to the wafer bending protector may be visible. In addition, the process of separating the wafer bending protector from one side of the wafer preferably comprises irradiating ultraviolet rays to weaken an adhesion strength.

These and other features of the present invention will be readily apparent to those of ordinary skill in the art upon review of the detailed description that follows.

### BRIEF DESCRIPTION OF THE DRAWINGS

The foregoing and other features and advantages of the present invention will become more apparent by describing in detail preferred embodiments thereof as illustrated in the accompanying drawings in which like reference characters refer to like parts throughout and in which:

FIG. 1 is a flow chart illustrating a semiconductor device manufacturing process including a wafer backside grinding process according to the present invention;

FIG. 2A illustrates a state of the wafer before the wafer backside grinding process of the present invention;

FIG. 2B illustrates a wafer bending protector according to the present invention installed before the wafer backside grinding process; and

FIG. 2C illustrates a state of the wafer after the wafer backside grinding process of the present invention.

### DETAILED DESCRIPTION OF PREFERRED EMBODIMENTS

Korean Patent Application No. 2001-2673, filed on Jan. 17, 2001, and entitled: “Semiconductor Wafer Backside Grinding Apparatus and Method,” is herein incorporated by reference in its entirety.

Hereinafter, preferred embodiments of the present invention will be described in detail with reference to the accompanying drawings.

A semiconductor wafer backside grinding apparatus and method according to the present invention are applied to a semiconductor manufacturing process between a fabrication process and an assembly process.

Generally, a semiconductor device manufacturing process includes a single crystal growing process, a device design process, a wafer fabrication process, a device assembly process, and a device inspection process. In the single crystal growing process, a single crystal silicon with high purity is produced, and the single crystal silicon is sliced into numerous wafers. In the device design process, a layout of an electric circuit embodied in a wafer is produced. In the wafer fabrication process, a mask manufacturing process of each layer for a designed electric circuit is performed and each layer is produced in sequence on a wafer surface to generate the electric circuit through many processes such as a photolithography process employing the mask, an etch process, a film growing process, etc. In the device assembly process, a fabricated wafer is divided and a lead frame for each of the devices is assembled. Finally, in the device inspection process, operations and functions of the devices produced are examined.

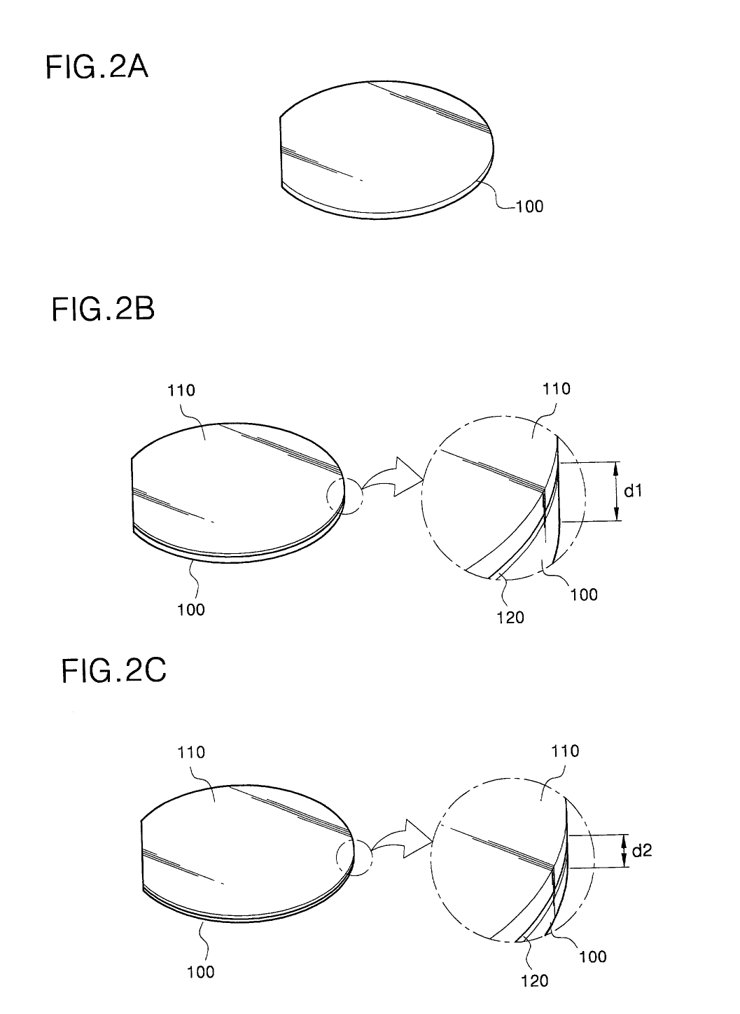

Referring to FIGS. 2A-2C, after patterning an electric circuit on the surface of the wafer 100 with a considerable thickness d1, a wafer backside grinding process is performed to reduce resistances to the electric conductivity of the device and to improve the heat conductivity of the wafer. The semiconductor wafer backside grinding apparatus according to the present invention attaches a wafer bending protector 110 to the backside of a wafer 100, wherein the wafer bending protector 110 prevents a wafer from bending during the wafer backside grinding process in which the backside of the wafer is ground to make a thinner wafer having a thickness d2 as shown in FIG. 2C.

The wafer bending protector 110 performs not only a conventional role as a protecting tape for preventing impurities from penetrating the wafer, but also serves as a bending protector for preventing a wafer made thin by the wafer backside grinding process from becoming bent. Preventing the wafer from becoming bent in the wafer backside grinding process allows subsequent processes to be performed more efficiently and reduces the likelihood of the wafer being broken in any subsequent processes.

For achieving the above-mentioned purposes, it is preferable that the wafer bending protector 110 is formed of a transparent plastic with a considerable strength, wherein one side of the wafer bending protector 110 attached to the wafer 100 is coated by an adhesive 120.

The adhesive 120 may preferably employ one of an ultraviolet adhesive for which an adhesive strength is nearly zero when an ultraviolet ray is irradiated, only an adhesive with a weak adhesion strength, or a mixture of an ultraviolet adhesive and an adhesive with a weak adhesion strength. The adhesive 120 may also employ other adhesion material.

Any thickness of the wafer bending protector 110 is allowed provided that the thickness is within a measurable range of a pre-determined measuring apparatus and does not cause any processing problems.

In other words, any material and thickness of the wafer bending protector 110 according to the present invention may be used. When the material of the wafer bending protector 110 is transparent, a considerable degree of wafer flatness may be maintained and additional process problems may be reduced.

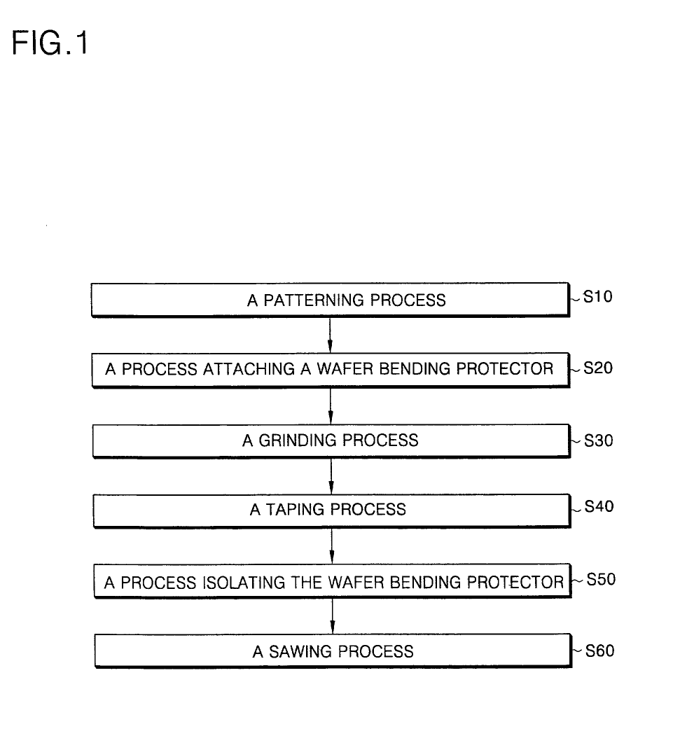

With reference to FIG. 1, FIG. 2A, FIG. 2B, and FIG. 2C, a wafer fabrication process employing the wafer bending protector 110 according to the present invention is described below.

As illustrated in FIGS. 1, 2A and 2B, the wafer fabrication process performs a process (S10) (of FIG. 1) producing a wafer with a predetermined pattern type and a predetermined thickness d1 on a wafer 100.

After attaching the wafer bending protector to a wafer (S20) (of FIG. 1), a grinding process (S30) (of FIG. 1) is performed to produce a wafer 100 having a pre-determined thickness d2.

The ground wafer attached to the wafer bending protector 110 is transferred into a wafer cassette by a transfer robot and an adhesion apparatus, and an assembly process is performed.

The assembly process includes a taping process (S40) (of FIG. 1) and a process of separating the wafer bending protector (S50) (of FIG. 1). In the taping process (S40) (of FIG. 1), a tape is attached on the backside of the wafer 100 to aid sawing each device in the wafer 100. In the separation process of the wafer bending protector (S50) (of FIG. 1), ultraviolet rays are irradiated to weaken the adhesion strength, and then, the wafer bending protector is separated from the wafer 100.

In a sawing process (S60) (of FIG. 1), each device on the wafer 100 is sawed by employing a diamond blade rotating at a high speed after the process of separating the wafer bending protector (S50) (of FIG. 1) is performed. Finally, a package process for each device produces semiconductor devices.

The semiconductor wafer backside grinding apparatus according to the present invention may produce thinner wafers than before, in a wafer of six inch diameter, eight inch diameter, and more particularly, twelve inch diameter.

In other words, the conventional semiconductor wafer backside grinding apparatus and method cannot grind a wafer to a thickness of less than 300 μm regardless of the diameter of the wafer 100. However, in the semiconductor wafer backside grinding apparatus and method according to the present invention, a wafer may be ground to a thickness of less than 100 μm. In addition, the semiconductor wafer backside grinding apparatus and method of the present invention may prevent a wafer from becoming bent in a grinding process and from breaking in a transfer state as a result of being bent. The wafer may be ground thinner than before, allowing the embodiment of a smaller semiconductor device package.

Therefore, the wafer bending protector and the method employing the wafer bending protector according to the present invention may prevent a wafer from becoming bent in a wafer backside grinding process due to being made thinner and allows for transfer of the ground wafer without the wafer being broken. Furthermore, grinding a wafer to a reduced thickness may also reduce the size of a semiconductor device package.

Preferred embodiments of the present invention have been disclosed herein and, although specific terms are employed, they are used and are to be interpreted in a generic and descriptive sense only and not for the purpose of limitation. Accordingly, it will be understood by those of ordinary skill in the art that various changes in form and details may be made without departing from the spirit and scope of the invention as set forth in the following claims.

What is claimed is:

1. A semiconductor wafer backside grinding apparatus comprising a wafer bending protector having a pre-determined strength attachable to a wafer to prevent the wafer from becoming bent and that protects the wafer from being penetrated by impurities in a grinding process.

2. A semicoductor wafer backside grinding apparatus as claimed in claim 1, wherein the wafer bending protector comprises a transparent material so that one side of the wafer attached to the wafer bending protector may be visible.

3. A semicoductor wafer backside grinding apparatus as claimed in claim 1, wherein one side of the wafer bending protector for attaching to the wafer is coated by an adhesive.

4. A semicoductor wafer backside grinding apparatus as claimed in claim 2, wherein one side of the wafer bending protector attaching to the wafer is coated by an adhesive.

5. A semicoductor wafer backside grinding apparatus as claimed in claim 3, wherein the adhesive comprises an adhesive selected from the group consisting of an ultraviolet adhesive for which an adhesive strength is nearly zero when an ultraviolet ray is irradiated, an adhesive with a weak adhesion strength, and a mixture of an ultraviolet adhesive and an adhesive with a weak adhesion strength.

6. A semicoductor wafer backside grinding apparatus as claimed in claim 4, wherein the adhesive comprises an adhesive selected from the group consisting of an ultraviolet adhesive for which an adhesive strength is nearly zero when an ultraviolet ray is irradiated, an adhesive with a weak adhesion strength, and a mixture of an ultraviolet adhesive and an adhesive with a weak adhesion strength.

7. A wafer fabrication method in a semiconductor wafer backside grinding apparatus, the wafer fabrication method comprising the steps of:
attaching a wafer bending protector to a wafer; and
separating the wafer bending protector from the wafer.

8. The wafer fabrication method as claimed in claim 7, wherein the wafer bending protector has a pre-determined strength to prevent the wafer from becoming bent and prevents impurities from penetrating a patterned side of the wafer in a grinding process.

9. The wafer fabrication method as claimed in claim 7, wherein during the separating of the wafer bending protector from the wafer, the wafer bending protector is separated from one side of the wafer.

10. The wafer fabrication method as claimed in claim 7, wherein the wafer bending protector comprises a transparent material that allows one side of the wafer attached to the wafer bending protector to be visible.

11. The wafer fabrication method as claimed in claim 8, wherein the wafer bending protector comprises a transparent material that allows one side of the wafer attached to the wafer bending protector to be visible.

12. The wafer fabrication method as claimed in claim 8, wherein the process of separating the wafer bending protector from the wafer comprises irradiating ultraviolet rays to weaken an adhesion strength between the wafer bending protector and the wafer.

13. The wafer fabrication method as claimed in claim 9, wherein the process of separating the wafer bending protector from one side of the wafer comprises irradiating ultraviolet rays to weaken an adhesion strength between the wafer bending protector and the wafer.
